(19) United States
(12) Patent Application Publication
(10) Pub. No.: US 2025/0218906 A1
(43) Pub. Date: Jul. 3, 2025

(54) RECONSTITUTED PASSIVE ASSEMBLIES FOR EMBEDDING IN THICK CORES

(71) Applicant: Intel Corporation, Santa Clara, CA (US)

(72) Inventors: Zhixin XIE, Chandler, AZ (US); Ziqing HAN, Los Angeles, CA (US); Srinivas Venkata Ramanuja PIETAMBARAM, Chandler, AZ (US); Jung Kyu HAN, Chandler, AZ (US); Gang DUAN, Chandler, AZ (US); Yingying ZHANG, Phoenix, AZ (US); Minglu LIU, Chandler, AZ (US); Manni MO, Maricopa, AZ (US); Kyle ARRINGTON, Gilbert, AZ (US); Clay ARRINGTON, Queen Creek, AZ (US); Bohan SHAN, Chandler, AZ (US); Ryan CARRAZZONE, Chandler, AZ (US); Yiqun BAI, Chandler, AZ (US); Ziyin LIN, Chandler, AZ (US); Jose WAIMIN, Gilbert, AZ (US); Dingying David XU, Chandler, AZ (US); Hongxia FENG, Chandler, AZ (US); Yongki MIN, Phoenix, AZ (US); Brandon C. MARIN, Gilbert, AZ (US)

(21) Appl. No.: 18/401,052

(22) Filed: Dec. 29, 2023

(51) Int. Cl. H01L 23/482; H01L 23/00

(52) U.S. Cl. CPC H01L 23/4821; H01L 24/05; H01L 24/29; H01L 24/97; H10D 1/68; H01L 2224/05009; H01L 2224/05025; H01L 2224/29009; H01L 2224/29025; H01L 2224/97; H01L 2924/01013; H01L 2924/01029; H01L 2924/0103; H01L 2924/1205; H01L 2924/1431

(57) ABSTRACT

Embodiments disclosed herein include apparatuses with assemblies comprising passive electrical devices that are embedded in a core of a package substrate. In an embodiment, such an apparatus may comprise a substrate with a first surface, a second surface opposite from the first surface, and a sidewall surface coupling the first surface to the second surface. In an embodiment the substrate comprises a passive electrical device. In an embodiment, a pad is on the first surface of the substrate, and a layer contacts the substrate. In an embodiment, the layer directly contacts the first surface and the sidewall surface of the substrate.

### BACKGROUND

As advanced packaging is enabling more aggressive computation capability, high power and high quality power delivery is needed to support all of the overlying chiplets. The ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Placing such passive components in deep cavities through the core can be problematic. For example, the passive components may shift or rotate during embedding.

### BRIEF DESCRIPTION OF THE DRAWINGS

FIG. 1 is a cross-sectional illustration of a core with an embedded passive component that has shifted during the embedding process, in accordance with an embodiment.

FIG. 2A is a cross-sectional illustration of an assembly in a core cavity where the assembly includes a component substrate that is embedded in a layer, in accordance with an embodiment.

FIG. 2B is a cross-sectional illustration of an assembly in a core cavity where the assembly includes a component substrate and a spacer substrate, in accordance with an embodiment.

FIG. 2C is a cross-sectional illustration of an assembly in a core cavity where the assembly includes a component substrate with a layer over the component substrate, in accordance with an embodiment.

FIG. 2D is a cross-sectional illustration of an assembly in a core cavity where the assembly includes component substrate with a layer comprising filler particles over the component substrate, in accordance with an embodiment.

FIG. 2E is a cross-sectional illustration of an assembly in a core cavity where the assembly includes a component substrate with a layer and a non-conductive film (NCF), in accordance with an embodiment.

FIGS. 3A-3D are cross-sectional illustrations depicting a process for forming assemblies with a reconstituted wafer process, in accordance with an embodiment.

FIG. 3E is a process flow diagram of a process for forming assemblies with a reconstituted wafer process, in accordance with an embodiment.

FIGS. 4A-4D are cross-sectional illustrations depicting a process for forming assemblies with a reconstituted wafer process, in accordance with an embodiment.

FIG. 4E is a process flow diagram of a process for forming assemblies with a reconstituted wafer process, in accordance with an embodiment.

FIGS. 5A-5C are cross-sectional illustrations depicting a process for forming assemblies with a wafer level process, in accordance with an embodiment.

FIG. 5D is a process flow diagram of a process for forming assemblies with a wafer level process, in accordance with an embodiment.

FIGS. 6A-6C are cross-sectional illustrations depicting a process for forming assemblies with a wafer level process, in accordance with an embodiment.

FIG. 6D is a process flow diagram of a process for forming assemblies with a wafer level process, in accordance with an embodiment.

FIGS. 6E-6H are cross-sectional illustrations depicting a process for embedding an assembly into a core, in accordance with an embodiment.

FIGS. 7A-7C are plan view illustrations depicting a process for forming assemblies with a wafer level process, in accordance with an embodiment.

FIGS. 8A-8C are cross-sectional illustrations depicting a process for embedding an assembly into a core, in accordance with an embodiment.

FIG. 8D is a process flow diagram of a process for embedding an assembly into a core, in accordance with an embodiment.

FIG. 9 is a cross-sectional illustration of an electronic system that comprises a package substrate with an assembly embedded in a core of the package substrate, in accordance with an embodiment.

FIG. 10 is a schematic of a computing device built in accordance with an embodiment.

### EMBODIMENTS OF THE PRESENT DISCLOSURE

Described herein are electronic systems, and more particularly, passive component assemblies with thickness modifications for embedding in thick cores, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

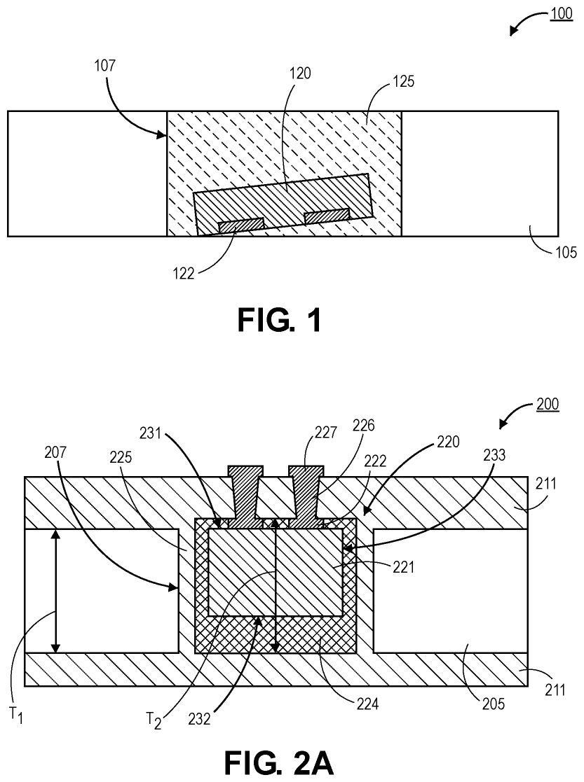

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIG. 1.

Referring now to FIG. 1, a cross-sectional illustration of a portion of a package substrate 100 is shown, in accordance with an embodiment. The package substrate 100 may comprise a core 105. The core 105 may sometimes be referred to simply as a substrate. The core 105 may be a glass core, an organic core, or the like. In an embodiment, a cavity 107 passes at least partially through the core 105. For example, in FIG. 1 the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. The movement of the component 120 may be due, at least in part, to the introduction of pressure to the component 120 during the filling process. As shown, the component 120 has tilted so that one side is raised up from the bottom of the core 105. This may make it difficult to make electrical contact to the pads 122 that are at the bottom of the component 120 in subsequent processing operations.

Accordingly, embodiments disclosed herein reduce movement of the passive component substrates by providing assemblies where component substrates are coupled to spacers or embedded in external layers. These additional spacers and/or layers augment the thickness of the component substrate so that the total thickness of the assembly more closely matches the thickness of the core. In several of the embodiments disclosed herein, the assemblies are fabricated through the use of a reconstituted substrate configuration. This allows for multiple assemblies to be fabricated in parallel in order to reduce costs and improve assembly efficiencies. For example, placing an assembly into a cavity may use a single pick-and-place operation compared to having to place (or deposit) multiple components or layers into the cavity.

In one embodiment, the assembly includes a component substrate that is at least partially embedded in a layer. The layer may be a dielectric layer that contacts a top surface, a bottom surface, and a sidewall surface of the component substrate. In another embodiment, the layer contacts the top surface and the sidewall surface of the component substrate. The bottom surface of the component substrate is coupled to a spacer substrate. In yet another embodiment, the layer may be provided only over the bottom surface of the component substrate. In some embodiments, the layer may include filler particles in order to improve coefficient of thermal expansion (CTE) matching. Additional embodiments may include a non-conductive film (NCF) that surrounds the pads of the component substrate. The NCF can improve bonding and prevent movement of the assembly during cavity filling operations.

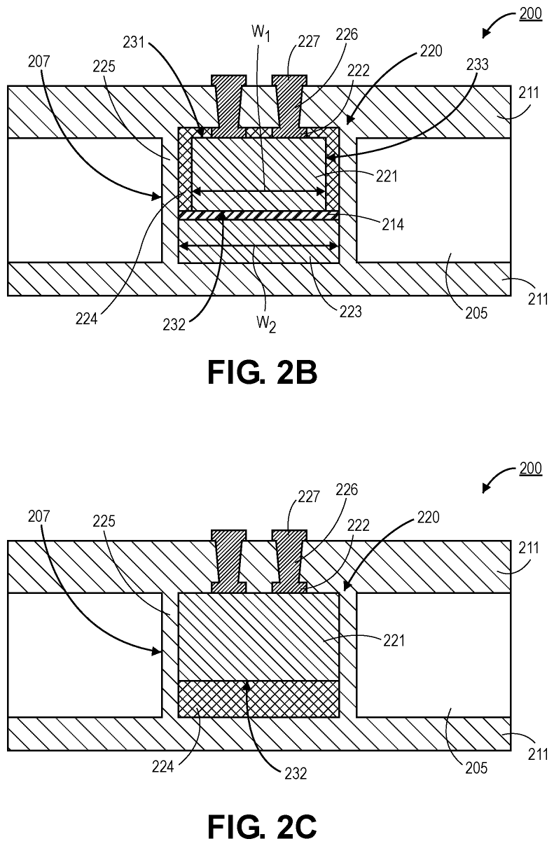

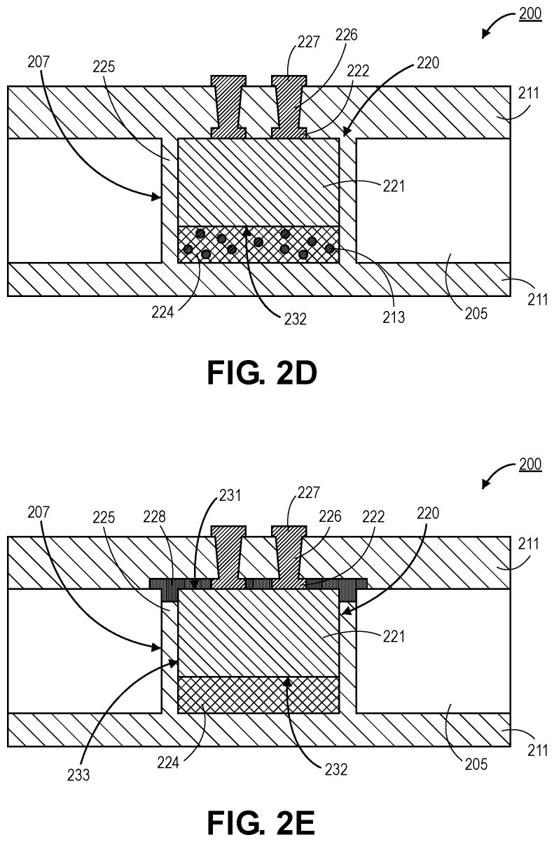

Referring now to FIG. 2A, a cross-sectional illustration of a portion of a package substrate 200 is shown, in accordance with an embodiment. In an embodiment, the package substrate 200 may comprise a core 205. The core 205 may be an organic core 205 or a glass core 205. In the case of a glass core 205, the glass core 205 may be substantially all glass. The glass core 205 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 205 may be distinguished from, for example, the “prepreg” or “RF4” core of a Printed Circuit Board (PCB) substrate which typically comprises glass fibers embedded in a resinous organic material, such as an epoxy.

The glass core 205 may have any suitable dimensions. In a particular embodiment, the glass core 205 may have a thickness that is approximately 50 μm or greater. For example, the thickness of the glass core 205 may be between approximately 50 μm and approximately 1.4 mm. Though, smaller or larger thicknesses may also be used. The glass core 205 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 205 (from an overhead plan view) may be between approximately 10 mm×10 mm and approximately 250 mm×250 mm. In an embodiment, the glass core 205 may have a first side that is perpendicular or orthogonal to a second side. In a more general embodiment, the glass core 205 may comprise a rectangular prism volume with sections (e.g., vias) removed and filled with other materials (e.g., metal, etc.).

The glass core 205 may comprise a single monolithic layer of glass. In other embodiments, the glass core 205 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 205 may each have a thickness less than approximately 50 μm. For example, discrete layers of glass in the glass core 205 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 205 may be any suitable glass formulation that has the necessary mechanical robustness and compatibility with semiconductor packaging manufacturing and assembly processes. For example, the glass core 205 may comprise aluminosilicate glass, borosilicate glass, alumino-borosilicate glass, silica, fused silica, or the like. In some embodiments, the glass core 205 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 205 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 205 may comprise at least 23 percent silicon (by weight) and at least 26 percent oxygen (by weight). In some embodiments, the glass core 205 may further comprise at least 5 percent aluminum (by weight).

In an embodiment, a cavity 207 may be provided through a thickness of the core 205. The cavity 207 may have sidewalls that are substantially vertical. Though, in other embodiments, the cavity 207 may have tapered, sloped, or otherwise non-planar sidewalls.

In an embodiment, an assembly 220 is inserted into the cavity 207. The core 205 may have a first thickness T₁ and the assembly 220 may have a second thickness T₂ that is substantially equal to the first thickness T₁. As used herein, “substantially equal” may refer to two values that are within ten percent of each other. For example, a thickness between 900 μm and 1,100 μm may be substantially equal to a thickness that is 1,000 μm. With substantially equal thicknesses between the assembly 220 and the core 205, embedding the assembly 220 with the fill layer 225 may not result in significant movement, displacement, and/or rotation the assembly 220. The fill layer 225 may be a mold material, an epoxy, an organic dielectric (e.g., a buildup film), or the like. In some embodiments, the fill layer 225 may be the same material as the buildup layers 211 above and/or below the core 205. Though, the fill layer 225 may also be a different material than the buildup layers 211.

In an embodiment, the assembly 220 may comprise a component substrate 221. The component substrate 221 may comprise one or more passive electrical devices (not shown). For example, the component substrate 221 may comprise one or more of an inductor, a capacitor, a resistor, or the like. In a particular embodiment, the component substrate 221 is a deep trench capacitor (DTC). The component substrate 221 may comprise any suitable material, such as a semiconductor (e.g., silicon), a glass, a ceramic, an organic dielectric, or the like. Other than pads 222, the component substrate 221 is shown as being a monolithic structure. That is, electrical routing, pads, plates, electrodes, vias, high-k dielectrics (e.g., for capacitors), magnetic material (e.g., for inductors), and other structures are omitted for simplicity. However, it is to be appreciated that these structures and any other necessary structures for enabling passive electrical devices may be integrated into or provided on the component substrate 221. In an embodiment, vias 226 and pads 227 may be provided in and/or on the buildup layers 211 and coupled to the pads 222.

In an embodiment, the assembly 220 may further comprise a layer 224 that contacts the component substrate 221. The layer 224 may contact one or more surfaces of the component substrate 221. For example, the layer 224 in FIG. 2A contacts a first surface 231, a second surface 232, and a sidewall surface 233 of the component substrate 221. In some embodiments, the component substrate 221 may be considered as being “embedded” within the layer 224. The layer 224 may also contact sidewalls of the pads 222 that extend up from the first surface 231 of the component substrate 221.

In an embodiment, the layer 224 may have a non-uniform thickness around the component substrate 221. For example, a thickness of the layer 224 over the sidewall surface 233 of the component substrate 221 may be smaller than a thickness of the layer 224 over the second surface 232 of the component substrate 221. In one embodiment, a thickness of the layer 224 over the first surface 231 of the component substrate 221 may be substantially equal to a thickness of the pads 222.

In an embodiment, the layer 224 may comprise a dielectric material. In one case, the dielectric material is an inorganic dielectric material, such as an oxide, a nitride, or the like. For example, inorganic dielectrics may comprise one or more of silicon, nitrogen, oxygen, and the like. In other embodiments, the dielectric material may be an organic dielectric material or an organic-inorganic composite material. Organic dielectrics may include polymers, epoxies, polyimides, or the like. In some instances, the dielectric material may comprise inorganic filler particles or the like. Embodiments may also include silicones, urethanes, or the like for the layer 224. In an embodiment, the dielectric material of the layer 224 may include a material that is compatible with molding processes, lamination processes, pressing processes, chemical vapor deposition (CVD), physical vapor deposition (PVD), or the like. In some embodiments, the layer 224 may further comprise filler particles (as will be described in greater detail below).

Referring now to FIG. 2B, a cross-sectional illustration of a portion of a package substrate 200 is shown, in accordance with an additional embodiment. In an embodiment, the package substrate 200 in FIG. 2B is similar to the package substrate 200 in FIG. 2A, with the exception of the structure of the assembly 220. Instead of having the layer 224 embedding the component substrate 221, the second surface 232 of the component substrate 221 is coupled to a spacer substrate 223. For example, an adhesive layer 214 may mechanically couple the component substrate 221 to the spacer substrate 223. The adhesive layer 214 may also contact a portion of the layer 224 in some embodiments.

In an embodiment, the spacer substrate 223 may comprise a material composition that is the same (or similar) as a material composition of the component substrate 221. For example, the component substrate 221 and the spacer substrate 223 may both comprise silicon in some embodiments. Matching material compositions between the spacer substrate 223 and the component substrate 221 may be beneficial because it reduces (or eliminates) CTE mismatch within the assembly 220. As such, reliability may be improved.

In an embodiment, the component substrate 221 may have a first width W₁, and the spacer substrate 223 may have a second width W₂. The second width W₂ may be larger than the first width W₁. In some instances, the second width W₂ may be substantially equal to a total width of the layer 224. For example, sidewalls of the layer 224 may be aligned with sidewalls of the spacer substrate 223.

Referring now to FIG. 2C, a cross-sectional illustration of a portion of a package substrate 200 is shown, in accordance with an additional embodiment. The package substrate 200 in FIG. 2C may be similar to the package substrate 200 in FIG. 2A, with the exception of the structure of the assembly 220. Instead of the layer 224 embedding the component substrate 221, the layer 224 is only provided along the second surface 232 of the component substrate 221. Such an embodiment may be the result of a wafer level processing operation used to form the assembly 220. That is, there may not be any dielectric material along the sidewalls of the component substrate 221 during the singulation process, and the sidewalls of the component substrate 221 are bare. However, after the embedding process, the fill layer 225 may directly contact the sidewalls of the component substrate 221 in some embodiments.

Referring now to FIG. 2D, a cross-sectional illustration of a portion of a package substrate 200 is shown, in accordance with yet another embodiment. The package substrate 200 in FIG. 2D may be similar to the package substrate 200 in FIG. 2C, with the exception of the material composition of the layer 224. Generally, the layer 224 in FIG. 2D may be a dielectric material similar to those described in greater detail above (e.g., an organic dielectric or an inorganic dielectric). However, the layer 224 may further comprise filler particles 213. The filler particles 213 may have any suitable volume percentage within the layer 224. For example, in a cross-section of the layer 224, filler particles 213 may occupy up to 80% of the total area, up to 50% of the total area, up to 25% of the total area, or up to 5% of the total area. Though, larger loading percentages may also be used in some embodiments. In an embodiment, the filler particles 213 may be micro-scale particles or nano-scale particles. For example, filler particles 213 within a given cross-section may have maximum lengths that are between 1 nm and 10 μm. Though, larger or smaller lengths may also be used in some embodiments.

In an embodiment, the filler particles 213 may include any suitable material. For example, filler particles 213 may comprise one or more of silica, BN/Al, ZnO, alumina, aluminum, carbon (e.g., carbon nanotubes, graphite, graphene, diamond, etc.) copper, silver, or the like. Filler particles 213 may provide one or more benefits to the performance of the assembly 220. For example, filler particles 213 may improve thermal performance when the filler particles 213 are thermally conductive materials. The filler particles 213 may also be used to modify the CTE of the layer 224 in order to improve CTE matching with the component substrate 221.

Referring now to FIG. 2E, a cross-sectional illustration of a portion of a package substrate 200 is shown, in accordance with another embodiment. In an embodiment, the package substrate 200 in FIG. 2E may be similar to the package substrate 200 in FIG. 2C with the addition of an NCF 228 around the pads 222. The NCF 228 may be used in order to improve the bonding of the assembly 220 during assembly. The NCF 228 may also help secure the assembly 220 during the filling of the cavity 207 with the fill layer 225.

In an embodiment, the NCF 228 may contact the first surface 231 of the component substrate 221. In some instances, the NCF 228 may also extend into the gap between the component substrate 221 and the sidewall of the cavity 207. For example, the NCF 228 may contact a portion of the sidewall 233 of the component substrate 221. In an embodiment, a width of the NCF 228 may be wider than a width of the component substrate 221. Though, in other embodiments, the NCF 228 may have a width that is substantially equal to a width of the component substrate 221, or the NCF 228 may have a width that is smaller than a width of the component substrate 221.

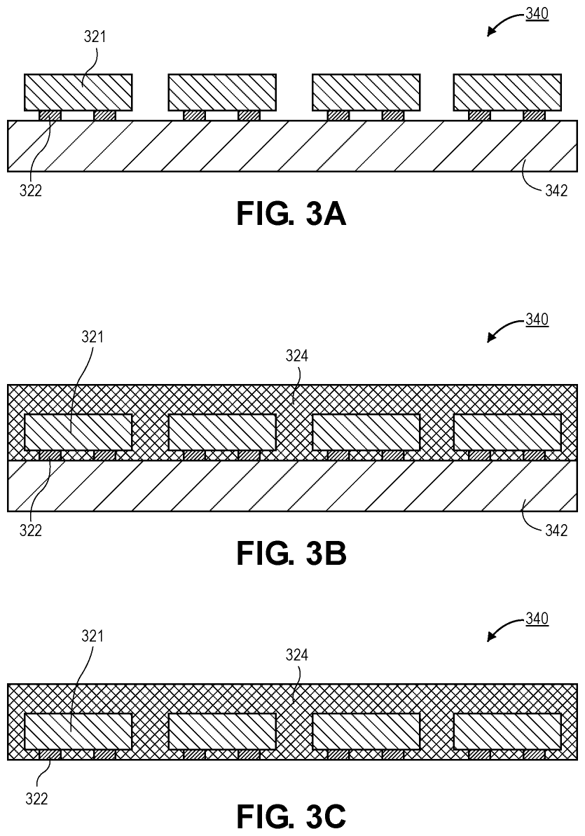

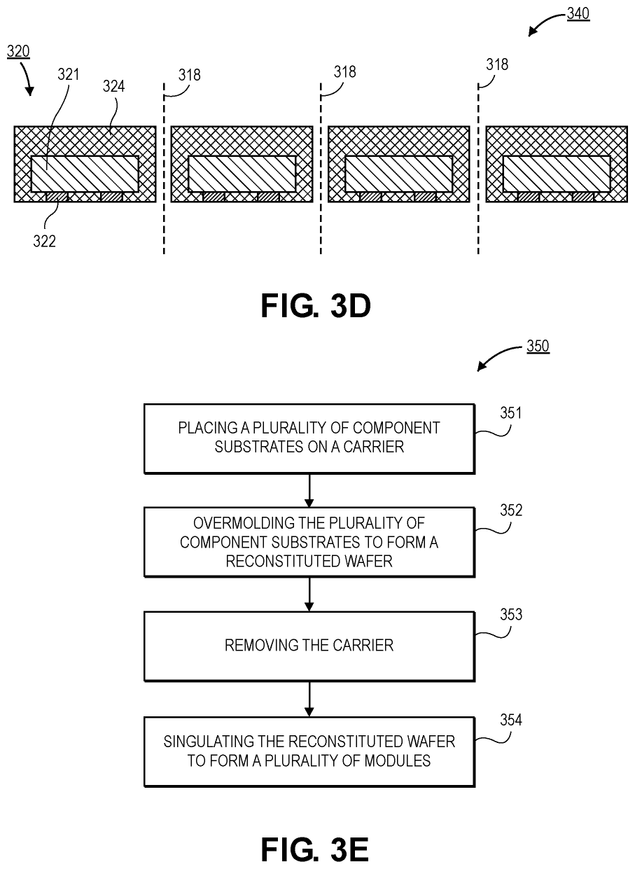

Referring now to FIGS. 3A-3D a series of cross-sectional illustrations depicting a process for forming a plurality of assemblies 320 from an assembly 340 with a reconstituted substrate process is shown, in accordance with an embodiment.

Referring now to FIG. 3A, a cross-sectional illustration of a portion of an assembly 340 is shown, in accordance with an embodiment. As shown, a plurality of component substrates 321 are mounted to a carrier 342. The component substrates 321 may be similar to any of the component substrates described in greater detail herein. The component substrates 321 may comprise passive electrical devices, such as an inductor, a capacitor, or a resistor. In an embodiment, pads 322 may be provided on the component substrates 321. The component substrates 321 may be placed on the carrier 342 with the pads 322 contacting the carrier 342. The carrier 342 may be any suitable material, such as a ceramic, a semiconductor, a metal, or the like.

Referring now to FIG. 3B, a cross-sectional illustration of the portion of the assembly 340 after a layer 324 is deposited over the component substrates 321 is shown, in accordance with an embodiment. The layer 324 may include a dielectric, such as an organic dielectric or an inorganic dielectric. In an embodiment, the layer 324 may be disposed over and around the component substrates 321 (including the pads 322) with any suitable process. For example, the layer 324 may be applied with a molding process, a lamination process, a pressing process, a CVD process, a PVD process, or the like.

Referring now to FIG. 3C, a cross-sectional illustration of the portion of the assembly 340 after the carrier 342 is removed is shown, in accordance with an embodiment. Removal of the carrier 342 exposes the bottom surfaces of the pads 322. The combined layer 324 and component substrates 321 may be considered a reconstituted substrate or a reconstituted wafer in some embodiments.

Referring now to FIG. 3D, a cross-sectional illustration of the portion of the assembly 340 after singulation to form a plurality of assemblies 320 is shown, in accordance with an embodiment. In an embodiment, the singulation may occur along lines 318 between component substrates 321. The singulation may include a laser ablation process, a sawing process, an etching process, or the like. The resulting assemblies 320 may include a component substrate 321 that is embedded in the layer 324. That is, the layer 324 may contact a top surface, a bottom surface, and sidewall surfaces of the component substrate 321.

Referring now to FIG. 3E, a process flow diagram of a process 350 for forming assemblies with a reconstituted wafer process is shown, in accordance with an embodiment. In an embodiment, the process 350 may begin with operation 351, which comprises placing a plurality of component substrates on a carrier. The operation 351 may be similar to the description and illustration provided herein with respect to FIG. 3A.

In an embodiment, process 350 may continue with operation 352, which comprises overmolding the plurality of component substrates to form a reconstituted wafer. The operation 352 may be similar to the description and illustration provided herein with respect to FIG. 3B.

In an embodiment, process 350 may continue with operation 353, which comprises removing the carrier. The operation 353 may be similar to the description and illustration provided herein with respect to FIG. 3C.

In an embodiment, process 350 may continue with operation 354, which comprises singulating the reconstituted wafer to form a plurality of assemblies. The operation 354 may be similar to the description and illustration provided herein with respect to FIG. 3D.

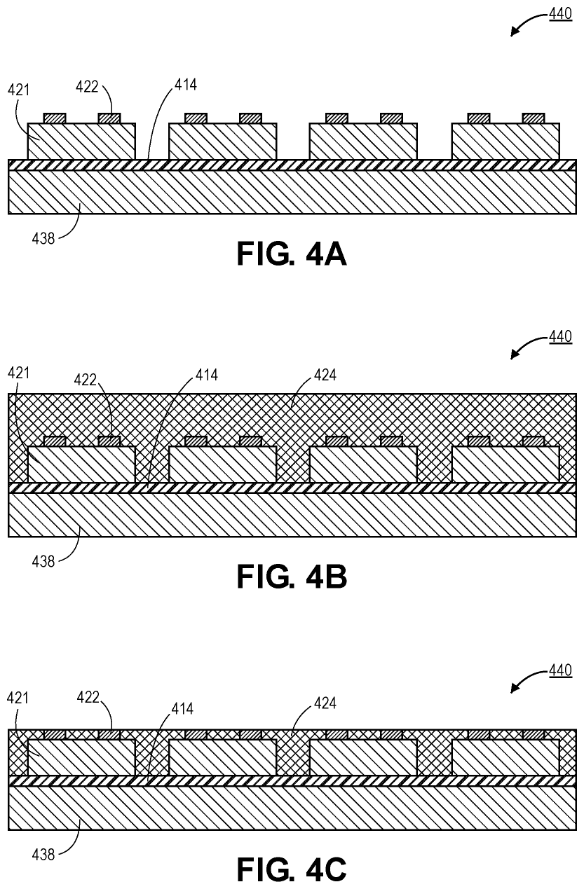

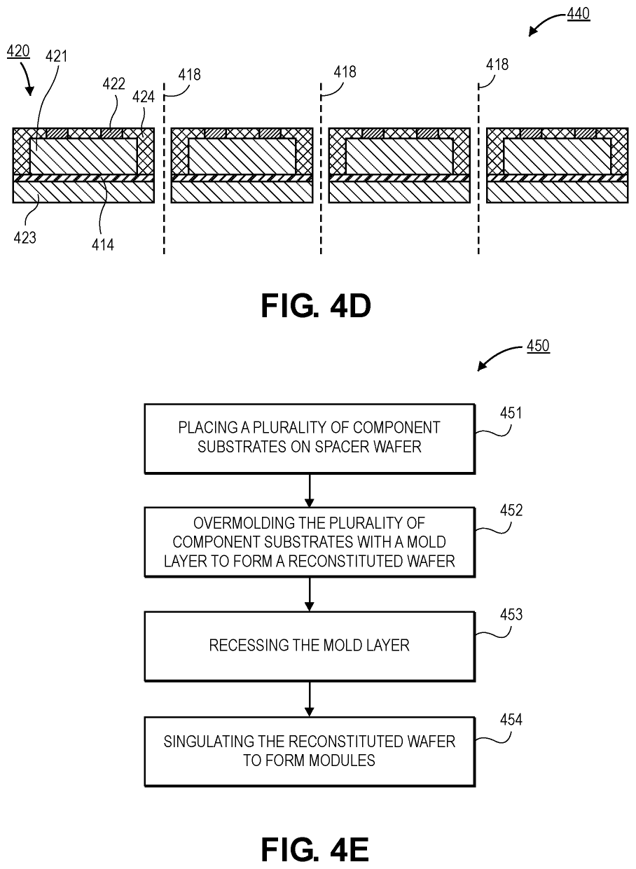

Referring now to FIGS. 4A-4D, a series of cross-sectional illustrations depicting a process for forming a plurality of assemblies 420 from an assembly 440 using a reconstituted wafer process is shown, in accordance with an additional embodiment.

Referring now to FIG. 4A, a cross-sectional illustration of a portion of an assembly 440 is shown, in accordance with an embodiment. In an embodiment, the assembly 440 may comprise a spacer wafer 438. A plurality of component substrate 421 may be mounted to the spacer wafer 438 by way of an adhesive layer 414 that extends across a top surface of the spacer wafer 428. In an embodiment, pads 422 of the component substrate 421 may face away from the spacer wafer 428.

In an embodiment, the component substrates 421 may be similar to any of the component substrates described in greater detail herein. For example, the component substrates 421 may comprise electrically passive devices, such as an inductor, a capacitor, or a resistor. In an embodiment the spacer wafer 438 may be a dummy structure without any integrated circuitry or features. In an embodiment, the spacer wafer 438 and the component substrates 421 comprise the same or similar material. For example, both the spacer wafer 438 and the component substrates 421 may comprise silicon.

Referring now to FIG. 4B, a cross-sectional illustration of the portion of the assembly 440 after a layer 424 is deposited over the component substrates 421 is shown, in accordance with an embodiment. The layer 424 may include a dielectric, such as an organic dielectric or an inorganic dielectric. In an embodiment, the layer 424 may be disposed over and around the component substrates 421 (including the pads 422) with any suitable process. For example, the layer 424 may be applied with a molding process, a lamination process, a pressing process, a CVD process, a PVD process, or the like.

Referring now to FIG. 4C, a cross-sectional illustration of the portion of the assembly 440 after a recessing operation is shown, in accordance with an embodiment. As shown, a top surface of the layer 424 may be polished back so that top surfaces of the pads 422 are exposed. The polishing operation may include a chemical mechanical planarization (CMP) process or the like. At this point the assembly 440 may be considered a reconstituted wafer or a reconstituted substrate. The layer 424 may cover a top surface of the component substrates 421 and sidewall surfaces of the component substrates 421.

Referring now to FIG. 4D, a cross-sectional illustration of the portion of the assembly 440 after singulation to form a plurality of assemblies 420 is shown, in accordance with an embodiment. In an embodiment, the singulation may occur along lines 418 between component substrates 421. The singulation may include a laser ablation process, a sawing process, an etching process, or the like. The resulting assemblies 420 may include a component substrate 421 that is partially embedded in the layer 424. The bottom surface of the component substrate 421 may be covered by the adhesive layer 414 which is attached to a spacer substrate 423. A width of the spacer substrate 423 may be greater than a width of the component substrate 421.

Referring now to FIG. 4E, a process flow diagram of a process 450 for forming assemblies with a reconstituted wafer process is shown, in accordance with an embodiment. In an embodiment, the process 450 may begin with operation 451, which comprises placing a plurality of component substrates on a spacer wafer. The operation 451 may be similar to the description and illustration provided herein with respect to FIG. 4A.

In an embodiment, process 450 may continue with operation 452, which comprises overmolding the plurality of component substrates with a mold layer to form a reconstituted wafer. The operation 452 may be similar to the description and illustration provided herein with respect to FIG. 4B.

In an embodiment, process 450 may continue with operation 453, which comprises recessing the mold layer. The operation 453 may be similar to the description and illustration provided herein with respect to FIG. 4C.

In an embodiment, process 450 may continue with operation 454, which comprises singulating the reconstituted wafer to form a plurality of assemblies. The operation 454 may be similar to the description and illustration provided herein with respect to FIG. 4D.

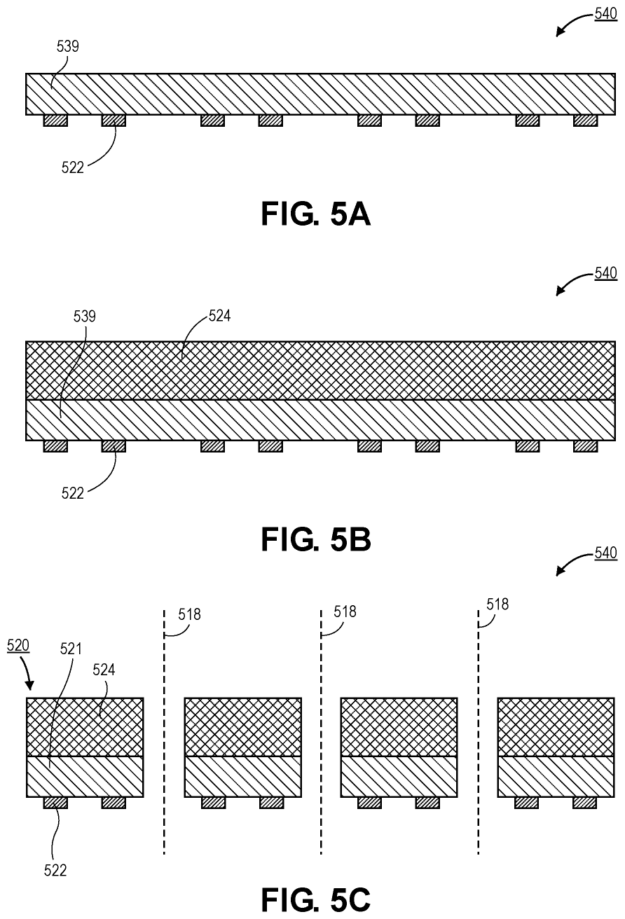

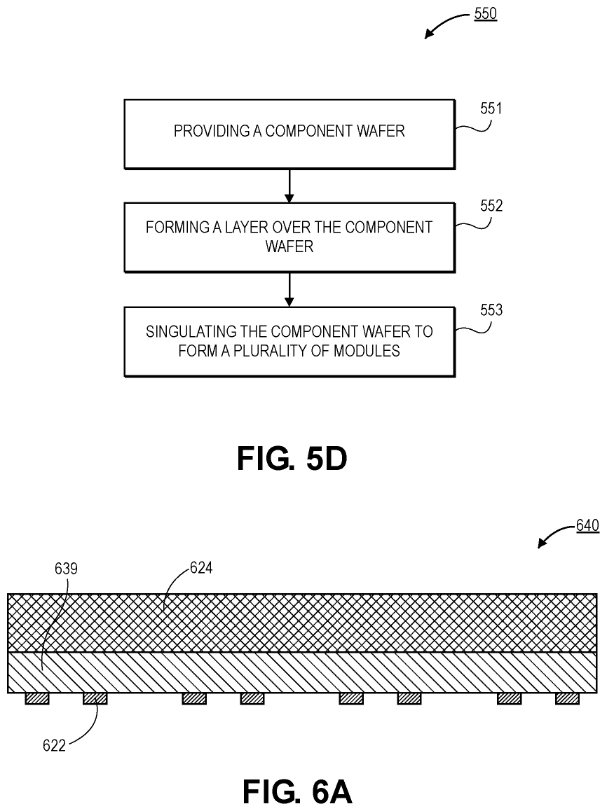

Referring now to FIGS. 5A-5C, a series of cross-sectional illustrations depicting a process for forming a plurality of assemblies 520 from an assembly 540 using a wafer process is shown, in accordance with an additional embodiment.

Referring now to FIG. 5A, a cross-sectional illustration of a portion of an assembly 540 is shown, in accordance with an embodiment. The assembly 540 may comprise a component wafer 539. The component wafer 539 may comprise a plurality of regions (not shown) that each include one or more electrically passive devices, such as an inductor, a capacitor, or a resistor. The component wafer 539 may also comprise a plurality of pads 522 that are coupled to each of the plurality of regions.

Referring now to FIG. 5B, a cross-sectional illustration of the portion of the assembly 540 after a layer 524 is formed over the component wafer 539 is shown, in accordance with an embodiment. The layer 524 may include a dielectric, such as an organic dielectric or an inorganic dielectric. In an embodiment, the layer 524 may be disposed over a backside of the component wafer 539 with any suitable process. For example, the layer 524 may be applied with a molding process, a lamination process, a pressing process, a CVD process, a PVD process, or the like.

Referring now to FIG. 5C, a cross-sectional illustration of the portion of the assembly 540 after singulation to form a plurality of assemblies 520 is shown, in accordance with an embodiment. In an embodiment, the singulation may occur along lines 518 between regions of the component wafer 539. The singulation may include a laser ablation process, a sawing process, an etching process, or the like. The resulting assemblies 520 may include a component substrate 521 that is covered by the layer 524. The component substrate 521 may comprise the one or more electrically passive devices.

Referring now to FIG. 5D, a process flow diagram of a process 550 for forming assemblies with a wafer process is shown, in accordance with an embodiment. In an embodiment, the process 550 may begin with operation 551, which comprises providing a component wafer. The operation 551 may be similar to the description and illustration provided herein with respect to FIG. 5A.

In an embodiment, process 550 may continue with operation 552, which comprises forming a layer over the component wafer. The operation 552 may be similar to the description and illustration provided herein with respect to FIG. 5B.

In an embodiment, process 550 may continue with operation 553, which comprises singulating the component wafer to form a plurality of assemblies. The operation 553 may be similar to the description and illustration provided herein with respect to FIG. 5C.

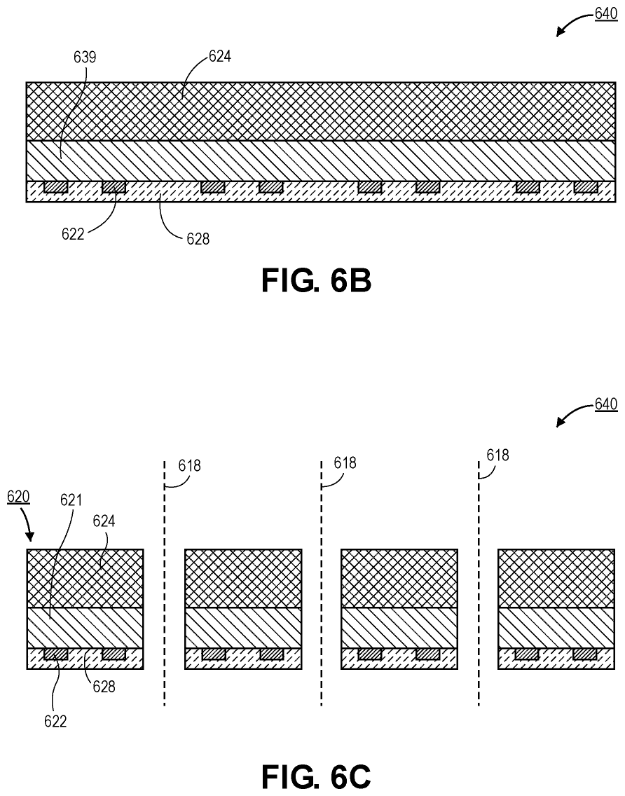

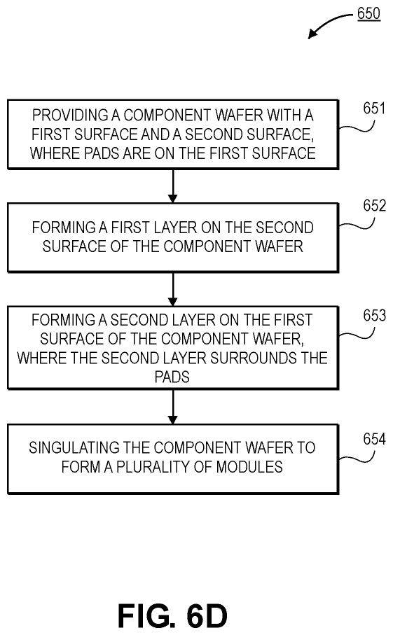

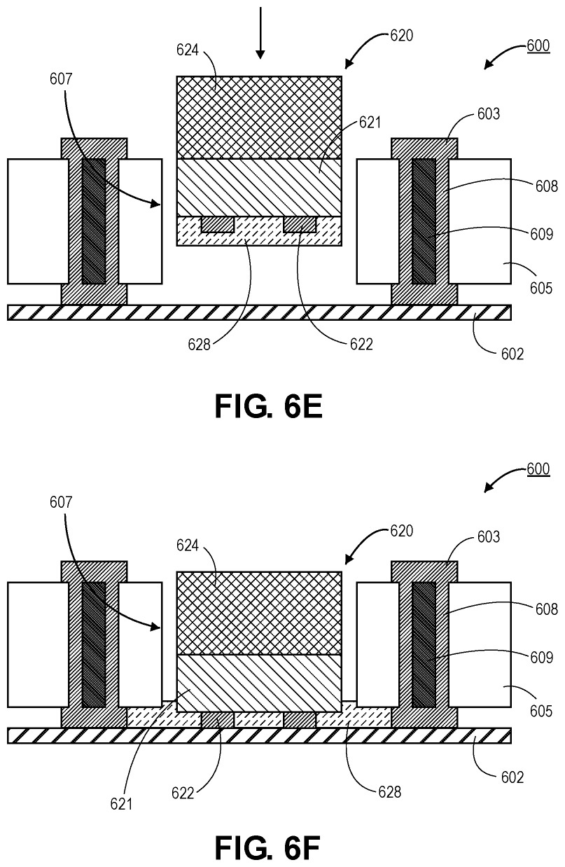

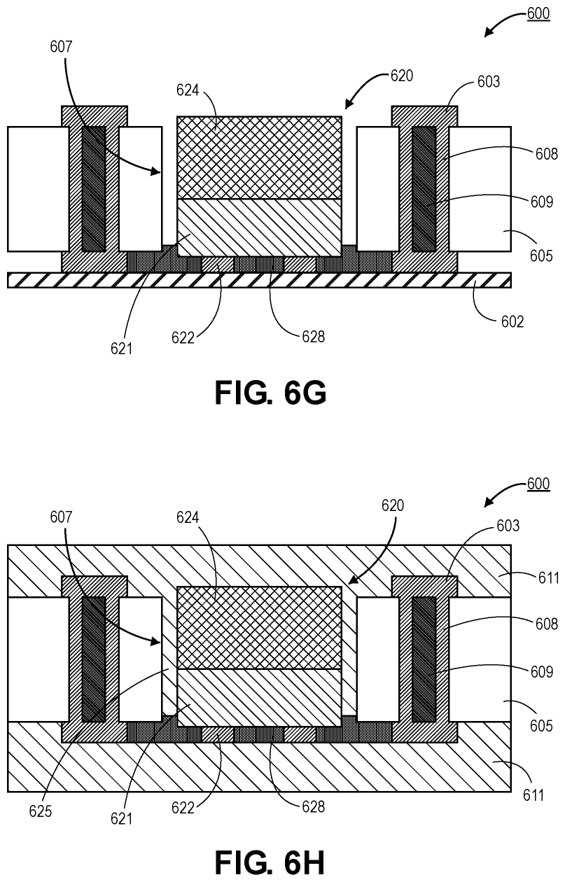

Referring now to FIGS. 6A-6C, a series of cross-sectional illustrations depicting a process for forming a plurality of assemblies 620 from an assembly 640 using a wafer process is shown, in accordance with an additional embodiment.

Referring now to FIG. 6A, a cross-sectional illustration of a portion of an assembly 640 is shown, in accordance with an embodiment. The assembly 640 may comprise a component wafer 639. The component wafer 639 may comprise a plurality of regions (not shown) that each include one or more electrically passive devices, such as an inductor, a capacitor, or a resistor. The component wafer 639 may also comprise a plurality of pads 622 that are coupled to each of the plurality of regions.

In an embodiment, a layer 624 is formed over the component wafer 639. The layer 624 may include a dielectric, such as an organic dielectric or an inorganic dielectric. In an embodiment, the layer 624 may be disposed over a backside of the component wafer 639 with any suitable process. For example, the layer 624 may be applied with a molding process, a lamination process, a pressing process, a CVD process, a PVD process, or the like.

Referring now to FIG. 6B, a cross-sectional illustration of the portion of the assembly 640 after an NCF 628 is applied over the bottom of the component wafer 639 is shown, in accordance with an embodiment. In an embodiment, a thickness of the NCF 628 may be greater than a thickness of the pads 622. In an embodiment, the NCF 628 may be applied with a lamination process or the like. The NCF 628 may be applied without curing. That is, the NCF 628 may remain pliable or deformable in order to aid with subsequent bonding operations.

Referring now to FIG. 6C, a cross-sectional illustration of the portion of the assembly 640 after singulation to form a plurality of assemblies 620 is shown, in accordance with an embodiment. In an embodiment, the singulation may occur along lines 618 between regions of the component wafer 639. The singulation may include a laser ablation process, a sawing process, an etching process, or the like. The resulting assemblies 620 may include a component substrate 621 that is covered by the layer 624. The component substrate 621 may comprise the one or more electrically passive devices. The NCF 628 may be provided on a surface of the component substrate 621 opposite from the layer 624. The NCF 628 may embed the pads 622.

Referring now to FIG. 6D, a process flow diagram of a process 650 for forming assemblies with a wafer process is shown, in accordance with an embodiment. In an embodiment, the process 650 may begin with operation 651, which comprises providing a component wafer with a first surface and a second surface, where pads are on the first surface. The operation 651 may be similar to the description and illustration provided herein with respect to FIG. 6A.

In an embodiment, process 650 may continue with operation 652, which comprises forming a first layer on the second surface of the component wafer. The operation 652 may be similar to the description and illustration provided herein with respect to FIG. 6A.

In an embodiment, process 650 may continue with operation 653, which comprises forming a second layer on the first surface of the component wafer, where the second layer surrounds the pads. The second layer may be an NCF. The operation 653 may be similar to the description and illustration provided herein with respect to FIG. 6B.

In an embodiment, process 650 may continue with operation 654, which comprises singulating the component wafer to form a plurality of assemblies. The operation 654 may be similar to the description and illustration provided herein with respect to FIG. 6C.

Referring now to FIGS. 6E-6H, a series of cross-sectional illustrations depicting a process for embedding an assembly 620 into a core 605 of a package substrate 600 is shown, in accordance with an embodiment.

Referring now to FIG. 6E, a cross-sectional illustration of a portion of a package substrate 600 is shown, in accordance with an embodiment. The package substrate 600 may comprise a core 605. The core 605 may be similar to any of the cores described in greater detail herein. A cavity 607 may be provided through a thickness of the core 605. In an embodiment, vias 608 may be provided through a thickness of the core 605 as well. In the illustrated embodiment, the vias 608 have a plated through hole (PTH) configuration. That is, the vias 608 are a hollow shell of electrically conductive material filled with an insulating plug 609. In other embodiments, the vias 608 may be fully filled with electrically conductive material. In an embodiments, pads 603 may be provided over and/or under the vias 608. In an embodiment, a tape 602 (or carrier) is provided below the core 605. The tape 602 may span an opening of the cavity 607 in order to provide a support surface on which to mount the assembly 620.

As indicated by an arrow, an assembly 620 may be placed into the cavity 607. The assembly 620 may be substantially similar to the assemblies 620 described above with respect to FIG. 6C. That is, the assembly 620 may comprise a component substrate 621 with an overlying layer 624. Pads 622 may be surrounded by an NCF 628.

Referring now to FIG. 6F, a cross-sectional illustration of the portion of the package substrate 600 after a bonding process couples the assembly 620 to the tape 602 is shown, in accordance with an embodiment. In an embodiment, the bonding process compresses the NCF 628 and causes the NCF 628 to spread laterally. This allows the pads 622 to contact the tape 602. The NCF 628 may now have a width that is greater than a width of the component substrate 621. In some embodiments, the NCF 628 spreads laterally until reaching an adjacent pad 603 or other dam like structure. The NCF 628 may also extend up a gap between a sidewall of the cavity 607 and a sidewall of the component substrate 621. In some instances, the NCF 628 contacts the sidewall of the component substrate 621.

Referring now to FIG. 6G, a cross-sectional illustration of the portion of the package substrate 600 after a curing process is shown, in accordance with an embodiment. In an embodiment, the curing process cures the NCF 628 so that the NCF 628 is not easily deformable. This locks the assembly 620 in place and prevents movement of the assembly 620 during subsequent processing operations. The cured NCF 628 is indicated by a change in the shading of the NCF 628 compared to the shading shown in FIG. 6F.

Referring now to FIG. 6H, a cross-sectional illustration of the portion of the package substrate 600 after the cavity 607 is filled with a fill layer 625 and buildup layers 611 are formed is shown, in accordance with an embodiment. In an embodiment, the tape 602 is removed, and a lamination process or the like is used to deposit buildup film material in the cavity 607 and over/under the core 605.

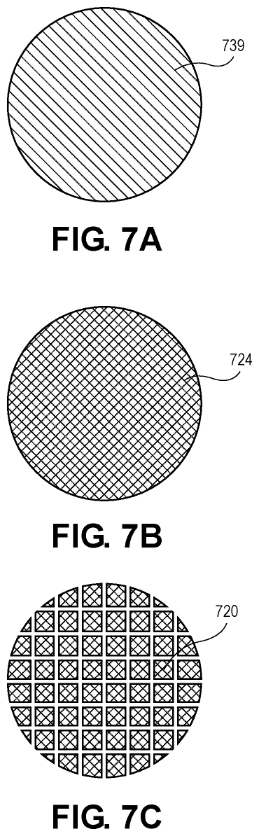

Referring now to FIGS. 7A-7C, a series of plan view illustrations depicting a process for forming assemblies with a wafer level process is shown, in accordance with an additional embodiment.

Referring now to FIG. 7A, a plan view illustration of a component wafer 739 is shown, in accordance with an embodiment. The component wafer 739 may comprise a plurality of regions (not shown) that each include one or more electrically passive devices, such as an inductor, a capacitor, or a resistor. The component wafer 739 may comprise a silicon wafer or the like.

Referring now to FIG. 7B, a layer 724 is formed over the component wafer 739. The layer 724 may include a dielectric, such as an organic dielectric or an inorganic dielectric. In an embodiment, the layer 724 may further comprise filler particles (not shown). The filler particles may have any suitable volume percentage within the layer 724. For example, in a cross-section of the layer 724, filler particles may occupy up to 80% of the total area, up to 50% of the total area, up to 25% of the total area, or up to 5% of the total area. Though, larger loading percentages may also be used in some embodiments. In an embodiment, the filler particles may be micro-scale particles or nano-scale particles. For example, filler particles within a given cross-section may have maximum lengths that are between 1 nm and 10 μm. Though, larger or smaller lengths may also be used in some embodiments.

In an embodiment, the filler particles may include any suitable material. For example, filler particles may comprise one or more of silica, BN/Al, ZnO, alumina, aluminum, carbon (e.g., carbon nanotubes, graphite, graphene, diamond, etc.) copper, silver, or the like. Filler particles may provide one or more benefits to the performance of the assemblies 720. For example, filler particles may improve thermal performance when the filler particles are thermally conductive materials. The filler particles may also be used to modify the CTE of the layer 724 in order to improve CTE matching with the component wafer 739.

In an embodiment, the layer 724 may be disposed over a backside of the component wafer 739 with any suitable process. For example, the layer 724 may be applied with a molding process, a lamination process, a pressing process, a CVD process, a PVD process, or the like.

Referring now to FIG. 7C, a plan view illustration of the wafer after singulation to form a plurality of assemblies 720 is shown, in accordance with an embodiment. In an embodiment, the singulation may occur along lines between regions of the component wafer 739. The singulation may include a laser ablation process, a sawing process, an etching process, or the like. The resulting assemblies 720 may include a component substrate (below the layer 724) that includes one or more electrically passive devices.

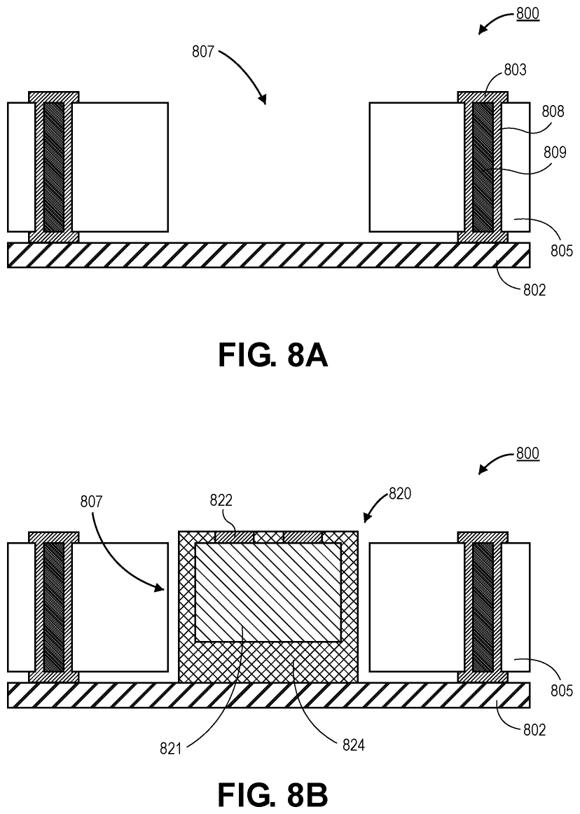

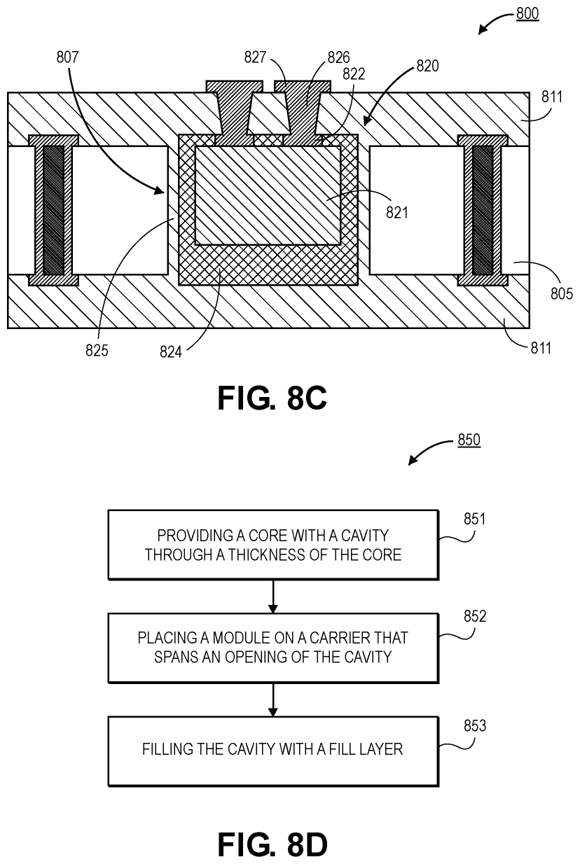

Referring now to FIG. 8A-8C, a series of cross-sectional illustrations depicting a process for embedding an assembly 820 into a core 805 of a package substrate 800 is shown, in accordance with an embodiment.

Referring now to FIG. 8A, a cross-sectional illustration of a portion of a package substrate 800 is shown, in accordance with an embodiment. The package substrate 800 may comprise a core 805. The core 805 may be similar to any of the cores described in greater detail herein. A cavity 807 may be provided through a thickness of the core 805. In an embodiment, vias 808 may be provided through a thickness of the core 805 as well. In the illustrated embodiment, the vias 808 have a PTH configuration. That is, the vias 808 are a hollow shell of electrically conductive material filled with an insulating plug 809. In other embodiments, the vias 808 may be fully filled with electrically conductive material. In an embodiments, pads 803 may be provided over and/or under the vias 808. In an embodiment, a tape 802 (or carrier) is provided below the core 805. The tape 802 may span an opening of the cavity 807 in order to provide a support surface on which to mount the assembly 820.

Referring now to FIG. 8B, a cross-sectional illustration of the portion of the package substrate 800 after a bonding process couples the assembly 820 to the tape 802 is shown, in accordance with an embodiment. In an embodiment, the assembly 820 may be similar to any of the assemblies described in greater detail herein. In the particular embodiment illustrated in FIG. 8B, the assembly 820 comprises a component substrate 821 that is embedded in a layer 824. The component substrate 821 may comprise one or more electrically conductive devices, such as an inductor, a capacitor, or a resistor. The layer 824 may be a dielectric layer (e.g., organic dielectric or inorganic dielectric) that is provided over a bottom surface, a top surface, and sidewall surfaces of the component substrate 821. Pads 822 may also be contacted and at least partially covered by the layer 824.

Referring now to FIG. 8C, a cross-sectional illustration of the portion of the package substrate 800 after the cavity 807 is filled with a fill layer 825 and buildup layers 811 are formed is shown, in accordance with an embodiment. In an embodiment, the tape 802 is removed, and a lamination process or the like is used to deposit buildup film material in the cavity 807 and over/under the core 805. Electrical routing (e.g., vias 826 and pads 827) may be coupled to the pads 822. The electrical routing may be fabricated with any suitable process.

Referring now to FIG. 8D, a process flow diagram of a process 850 for embedding an assembly in a core is shown, in accordance with an embodiment. In an embodiment, the process 850 may begin with operation 851, which comprises providing a core with a cavity through a thickness of the core. The operation 851 may be similar to the description and illustration provided herein with respect to FIG. 8A.

In an embodiment, process 850 may continue with operation 852, which comprises placing an assembly on a carrier that spans an opening of the cavity. The operation 852 may be similar to the description and illustration provided herein with respect to FIG. 8B.

In an embodiment, process 850 may continue with operation 853, which comprises filling the cavity with a fill layer. The operation 853 may be similar to the description and illustration provided herein with respect to FIG. 8C.

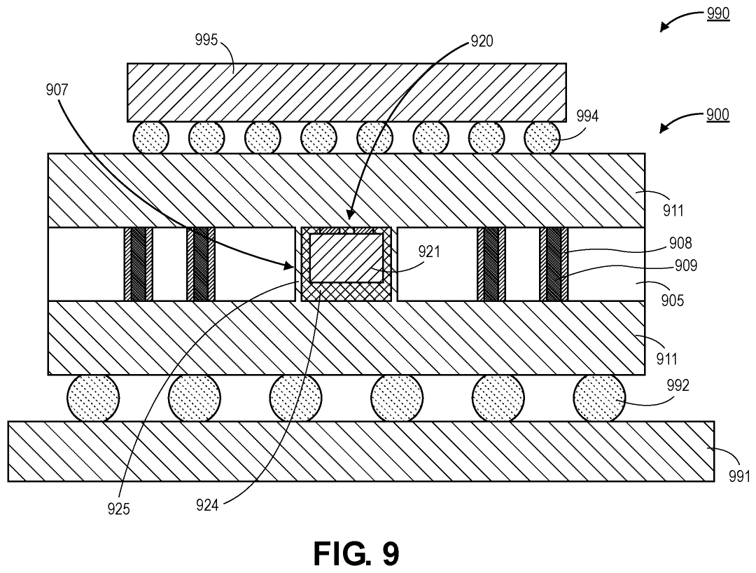

Referring now to FIG. 9, a cross-sectional illustration of an electronic system 990 is shown, in accordance with an embodiment. In an embodiment, the electronic system 990 comprises a board, such as a printed circuit board (PCB), a motherboard, or the like. In an embodiment, the board 990 is coupled to a package substrate 900 by interconnects 992. The interconnects 992 may be second level interconnects (SLIs), such as solder balls, sockets, pins, or the like.

In an embodiment, the package substrate 900 may be similar to any of the package substrates described herein. For example, the package substrate 900 may include a core 905 (e.g., a glass core 905 or an organic core 905) with buildup layers 911 above and below the core 905. The core 905 may comprise vias 908. In FIG. 9, the vias 908 are filled with an insulating plug 909. A cavity 907 may be provided through a thickness of the core 905.

In an embodiment, an assembly 920 may be set into the cavity 907. The assembly 920 may be similar to any of the assemblies described in greater detail herein. For example, the assembly 920 may comprise a component substrate 921 that is embedded in a layer 924. In FIG. 9, the component substrate 921 is at least partially covered on at least three surfaces by the layer 924. Though, fewer surfaces of the component substrate 921 may be covered in other embodiments. Additionally, a spacer substrate (not shown) may be included in some embodiments. A fill layer 925 may line the assembly 920 and fill a remaining portion of the cavity 907.

In an embodiment, one or more dies 995 may be coupled to the package substrate 900 by interconnects 994. The interconnects 994 may comprise first level interconnects (FLIs), such as solder balls, copper bumps, hybrid bonding interfaces, or the like. The die 995 may be any type of die, such as a central processing unit (CPU), a graphics processing unit (GPU), an XPU, a communications die, a memory die, an application specific integrated circuit (ASIC), a field programmable gate array (FPGA), or the like. In an embodiment, the assembly 920 is electrically coupled to the one or more dies 995 in order to control and/or improve power delivery that is provided to the die 995.

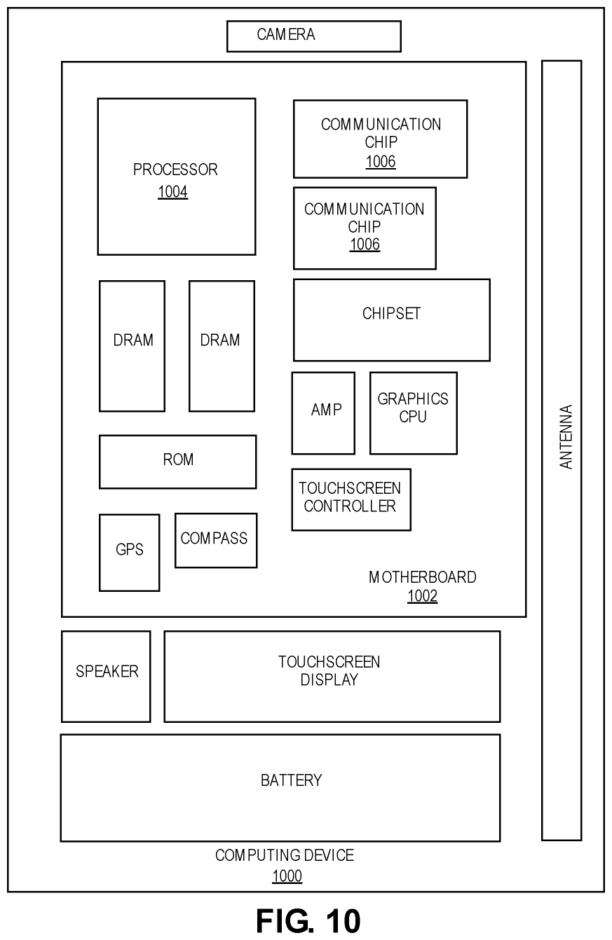

FIG. 10 illustrates a computing device 1000 in accordance with one implementation of the disclosure. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the disclosure, the integrated circuit die of the processor may be part of an electronic package that includes a core with an embedded assembly that includes a component substrate that is contacted by a dielectric layer, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the disclosure, the integrated circuit die of the communication chip may be part of an electronic package that includes a core with an embedded assembly that includes a component substrate that is contacted by a dielectric layer, in accordance with embodiments described herein.

In an embodiment, the computing device 1000 may be part of any apparatus. For example, the computing device may be part of a personal computer, a server, a mobile device, a tablet, an automobile, or the like. That is, the computing device 1000 is not limited to being used for any particular type of system, and the computing device 1000 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first surface, a second surface opposite from the first surface, and a sidewall surface coupling the first surface to the second surface, and wherein the substrate comprises a passive electrical device; a pad on the first surface of the substrate; and a layer that contacts the substrate, wherein the layer directly contacts the first surface and the sidewall surface of the substrate.

Example 2: the apparatus of Example 1, wherein the layer comprises an inorganic dielectric material.

Example 3: the apparatus of Example 1, wherein the layer comprises an organic dielectric material.

Example 4: the apparatus of Examples 1-3, wherein the layer comprises filler particles.

Example 5: the apparatus of claim 4, wherein the filler particles comprise one or more of silicon, oxygen, boron, nitrogen, aluminum, zinc, aluminum, carbon, copper, or silver.

Example 6: the apparatus of Examples 1-5, further comprising: a spacer substrate coupled to the second surface of the substrate.

Example 7: the apparatus of Example 6, wherein the substrate has a first width and the spacer substrate has a second width, and wherein the second width is greater than the first width.

Example 8: the apparatus of Example 6 or Example 7, wherein the spacer substrate and the substrate comprise the same material.

Example 9: the apparatus of Examples 1-8, wherein the layer contacts the second surface of the substrate.

Example 10: an apparatus, comprising: a first substrate; a cavity through a thickness of the first substrate; an assembly in the cavity, wherein the assembly comprises: a second substrate, wherein the second substrate comprises an electrically passive device; a pad on the second substrate; and a first layer coupled to the second substrate, wherein the first layer directly contacts at least one surface of the second substrate; and a second layer around the assembly and in the cavity.

Example 11: the apparatus of Example 10, wherein the first layer fully embeds the second substrate.

Example 12: the apparatus of Example 10 or Example 11, wherein the assembly further comprises: a third substrate coupled to the second substrate by an adhesive.

Example 13: the apparatus of Examples 10-12, wherein the first layer comprises filler particles.

Example 14: the apparatus of Examples 10-13, further comprising: a third layer on the second substrate that contacts the pad.

Example 15: the apparatus of Example 14, wherein a width of the third layer is greater than a width of the second substrate.

Example 16: the apparatus of Examples 10-15, wherein the first substrate comprises an organic dielectric or a glass layer with a rectangular prism form factor.

Example 17: an apparatus, comprising: a board; a package substrate coupled to the board, wherein the package substrate comprises: a core with a cavity through a thickness of the core, wherein the core has a first thickness; an assembly embedded in the cavity, wherein the assembly has a second thickness that is substantially equal to the first thickness, and wherein the assembly comprises: a component substrate with an electrically passive device, wherein the component substrate comprises silicon; and a layer that directly contacts at least one surface of the component substrate, wherein the layer is an organic dielectric or an inorganic dielectric; and a die coupled to the package substrate.

Example 18: the apparatus of Example 17, wherein the assembly further comprises: a spacer substrate coupled to the component substrate, wherein a width of the spacer substrate is greater than a width of the component substrate.

Example 19: the apparatus of Example 17 or Example 18, wherein the layer contacts a top surface, a bottom surface, and a sidewall surface of the component substrate.

Example 20: the apparatus of Example 17, wherein the apparatus is part of a personal computer, a server, a mobile device, a tablet, or an automobile.

What is claimed is:

1. An apparatus, comprising:
a substrate with a first surface, a second surface opposite from the first surface, and a sidewall surface coupling the first surface to the second surface, and wherein the substrate comprises a passive electrical device;
a pad on the first surface of the substrate; and
a layer that contacts the substrate, wherein the layer directly contacts the first surface and the sidewall surface of the substrate.

2. The apparatus of claim 1, wherein the layer comprises an inorganic dielectric material.

3. The apparatus of claim 1, wherein the layer comprises an organic dielectric material.

4. The apparatus of claim 1, wherein the layer comprises filler particles.

5. The apparatus of claim 4, wherein the filler particles comprise one or more of silicon, oxygen, boron, nitrogen, aluminum, zinc, aluminum, carbon, copper, or silver.

6. The apparatus of claim 1, further comprising:
a spacer substrate coupled to the second surface of the substrate.

7. The apparatus of claim 6, wherein the substrate has a first width and the spacer substrate has a second width, and wherein the second width is greater than the first width.

8. The apparatus of claim 6, wherein the spacer substrate and the substrate comprise the same material.

9. The apparatus of claim 1, wherein the layer contacts the second surface of the substrate.

10. An apparatus, comprising:
a first substrate;
a cavity through a thickness of the first substrate;
an assembly in the cavity, wherein the assembly comprises:
a second substrate, wherein the second substrate comprises an electrically passive device;
a pad on the second substrate; and
a first layer coupled to the second substrate, wherein the first layer directly contacts at least one surface of the second substrate; and
a second layer around the assembly and in the cavity.

11. The apparatus of claim 10, wherein the first layer fully embeds the second substrate.

12. The apparatus of claim 10, wherein the assembly further comprises:
a third substrate coupled to the second substrate by an adhesive.

13. The apparatus of claim 10, wherein the first layer comprises filler particles.

14. The apparatus of claim 10, further comprising:
a third layer on the second substrate that contacts the pad.

15. The apparatus of claim 14, wherein a width of the third layer is greater than a width of the second substrate.

16. The apparatus of claim 10, wherein the first substrate comprises an organic dielectric or a glass layer with a rectangular prism form factor.

17. An apparatus, comprising:
a board;
a package substrate coupled to the board, wherein the package substrate comprises:
a core with a cavity through a thickness of the core, wherein the core has a first thickness;
an assembly embedded in the cavity, wherein the assembly has a second thickness that is substantially equal to the first thickness, and wherein the assembly comprises:
a component substrate with an electrically passive device, wherein the component substrate comprises silicon; and
a layer that directly contacts at least one surface of the component substrate, wherein the layer is an organic dielectric or an inorganic dielectric; and
a die coupled to the package substrate.

18. The apparatus of claim 17, wherein the assembly further comprises:
a spacer substrate coupled to the component substrate, wherein a width of the spacer substrate is greater than a width of the component substrate.

19. The apparatus of claim 17, wherein the layer contacts a top surface, a bottom surface, and a sidewall surface of the component substrate.

20. The apparatus of claim 17, wherein the apparatus is part of a personal computer, a server, a mobile device, a tablet, or an automobile.
